(19) United States
(12) Patent Application Publication
(10) Pub. No.: US 2024/0321684 A1
(43) Pub. Date: Sep. 26, 2024

(54) CERAMIC SUBSTRATE AND MANUFACTURING METHOD THEREOF

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/577,656

(22) PCT Filed: Jul. 6, 2022
(86) PCT No.: PCT/KR2022/009707

§ 371 Date: Jan. 8, 2024

(30) Foreign Application Priority Data
Jul. 9, 2021 (KR) 10-2021-0090497

(51) Int. Cl. H01L 23/473; H01L 21/48; H01L 23/15; H01L 23/31

(52) U.S. Cl. CPC H01L 23/473; H01L 21/4857; H01L 21/4867; H01L 21/4882; H01L 23/15; H01L 23/3142

(57) ABSTRACT

The present invention relates to a ceramic substrate and a manufacturing method thereof, the ceramic substrate comprising: a ceramic base material; a first metal sheet attached to an upper portion of the ceramic base material and provided in the form of a circuit pattern; and a second metal sheet attached to a lower portion of the ceramic base material. The second metal sheet may include a flat portion in contact with the lower surface of the ceramic base material and a plurality of heat dissipation fins that are spaced apart from each other and protrude from a lower portion of the flat portion, wherein the heat dissipation fins are in contact with a liquid refrigerant.

### TECHNICAL FIELD

The present disclosure relates to a ceramic substrate and a method of manufacturing the same, and more specifically, to a ceramic substrate, which has a structure in which a metal sheet including a plurality of heat dissipation fins for water-cooled heat dissipation and a ceramic base are integrated, and a method of manufacturing the same.

### BACKGROUND ART

In general, electric vehicles require an inverter for converting a direct current voltage provided from a high-voltage battery into an alternating current three-phase voltage to drive a motor.

This inverter is assembled with a power module for adjusting a high voltage of a driving battery to a state suitable for the motor and supplying the adjusted voltage. The power module includes a semiconductor chip for converting conversion, and the semiconductor chip generates high temperature heat due to a high-voltage and high-current operation. When this heat continues, there is a problem in that the semiconductor chip deteriorates, and the performance of the power module deteriorates.

In order to solve this, a heat sink is provided on at least one surface of a ceramic or metal substrate to prevent a deterioration phenomenon of the semiconductor chip due to heat through a heat-dissipation function of the heat sink.

The heat sink is made of a metal material with a high thermal conductivity, such as copper and aluminum, and since the heat sink made of metal also has a limit in heat dissipation, when heat exceeding the limit or more is generated, cooling efficiency is degraded rapidly, causing a failure.

In addition, there is a problem in that the characteristics of the substrate on which the semiconductor chip is mounted are degraded due to the occurrence of bending or the like caused by heat.

### SUMMARY OF INVENTION

### Technical Problem

The present disclosure has been made in efforts to solve the problems and is directed to providing a ceramic substrate capable of effectively dissipating heat generated from a semiconductor chip, and a method of manufacturing the same.

### Solution to Problem

In order to achieve the object, a ceramic substrate according to an embodiment of the present disclosure includes a ceramic base, a first metal sheet bonded to an upper portion of the ceramic base and provided in a circuit pattern shape, and a second metal sheet bonded to a lower portion of the ceramic base, wherein the second metal sheet includes a flat portion in contact with a lower surface of the ceramic base, and a plurality of heat dissipation fins formed to protrude from a lower portion of the flat portion at intervals and in contact with liquid refrigerant.

The plurality of heat dissipation fins may be disposed in a refrigerant circulation unit in which an internal flow path from an inlet to an outlet is formed and may be in direct contact with the liquid refrigerant consecutively circulating along the internal flow path. The plurality of heat dissipation fins may have an aspect ratio of 1:3.

Materials of the first metal sheet and the second metal sheet may be any one of Cu, Al, and a Cu alloy.

The ceramic substrate may further include a bonding layer disposed between a lower surface of the first metal sheet and an upper surface of the ceramic base and between the lower surface of the ceramic base and the flat portion of the second metal sheet, wherein the bonding layer may be made of a material including at least one of Ag and AgCu.

Meanwhile, the flat portion of the second metal sheet may have a multi-layer structure and at least adjacent two layers of the multi-layer may be made of different metal materials.

Here, the flat portion may include an intermediate layer, an upper metal layer formed on an upper surface of the intermediate layer, and a lower metal layer formed on a lower surface of the intermediate layer, the upper metal layer and the lower metal layer may be made of the same metal material, and the intermediate layer may be made of a different metal material from the upper metal layer and the lower metal layer.

A material of the intermediate layer may be any one of CuMo and Mo, and materials of the upper metal layer and the lower metal layer may be any one of Cu, Al, and a Cu alloy.

A method of manufacturing a ceramic substrate according to an embodiment of the present disclosure includes preparing a ceramic base, preparing a first metal sheet having a circuit pattern shape, preparing a second metal sheet provided with a plurality of heat dissipation fins, and bonding the first metal sheet to an upper portion of the ceramic base and bonding the second metal sheet to a lower portion of the ceramic base, wherein in the preparing of the second metal sheet, the plurality of heat dissipation fins are formed to protrude from a lower portion of a flat portion in contact with a lower surface of the ceramic base at intervals and provided to be in contact with liquid refrigerant.

The bonding may include arranging a bonding layer between a lower surface of the first metal sheet and an upper surface of the ceramic base and between the lower surface of the ceramic base and the flat portion of the second metal sheet, and brazing the first metal sheet, the ceramic base, and the second metal sheet by melting the bonding layer.

In the arranging of the bonding layer, the bonding layer made of a material including at least one of Ag and AgCu may be disposed by any one method of plating, paste application, and foil attachment.

### Advantageous Effects of Invention

According to the present disclosure, since the ceramic substrate is a ceramic substrate having a direct cooling structure in which the plurality of heat dissipation fins are provided, and the second metal sheet with high thermal conductivity is brazed directly to the lower surface of the ceramic base, it is possible to maximize the heat dissipation performance, save energy and costs by simplifying the process, and implement weight reduction and miniaturization.

In addition, according to the present disclosure, since the ceramic substrate has the water-cooled heat dissipation structure in which the plurality of heat dissipation fins are cooled by being in direct contact with the consecutively circulating liquid refrigerant, it is possible to absorb and dissipate heat quickly by varying the flow rate of the liquid refrigerant and maximize the heat dissipation effect compared to the conventional air-cooled heat dissipation structure.

In addition, according to the present disclosure, by forcibly cooling the plurality of heat dissipation fins by the consecutively circulating liquid refrigerant even when the high temperature heat is generated from the semiconductor chip and the like, it is possible to prevent the overheating of the ceramic base and maintain the ceramic substrate at the constant temperature to prevent the deterioration of the semiconductor chip.

In addition, according to the present disclosure, since the liquid refrigerant is provided to flow between the plurality of heat dissipation fins, it is possible to easily control the flow of the liquid refrigerant as the number and arrangement of plurality of heat dissipation fins change.

### BRIEF DESCRIPTION OF DRAWINGS

FIG. 1 is a conceptual diagram illustrating a configuration in which a ceramic substrate according to an embodiment of the present disclosure is mounted on a refrigerant circulation unit and a circulation driving unit is connected to the refrigerant circulation unit.

FIG. 2 is a perspective view illustrating the ceramic substrate according to the embodiment of the present disclosure.

FIG. 3 is an exploded perspective view illustrating a bottom surface side of the ceramic substrate according to the embodiment of the present disclosure.

FIG. 4 is a bottom view illustrating the ceramic substrate according to the embodiment of the present disclosure.

FIG. 5 is a side view illustrating a modified example in which the ceramic substrate according to the embodiment of the present disclosure has a different flat portion of a second metal sheet.

FIG. 6 is a flowchart illustrating a method of manufacturing the ceramic substrate according to the embodiment of the present disclosure.

### DESCRIPTION OF EMBODIMENTS

Hereinafter, embodiments of the present disclosure will be described in detail with reference to the accompanying drawings.

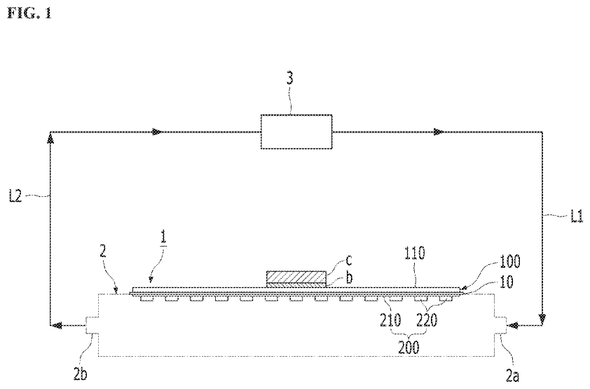

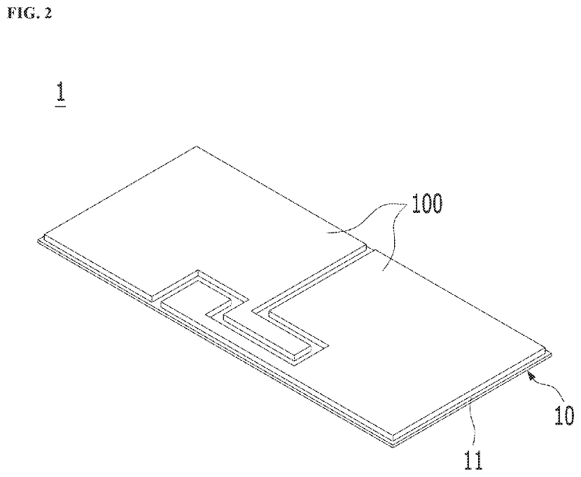

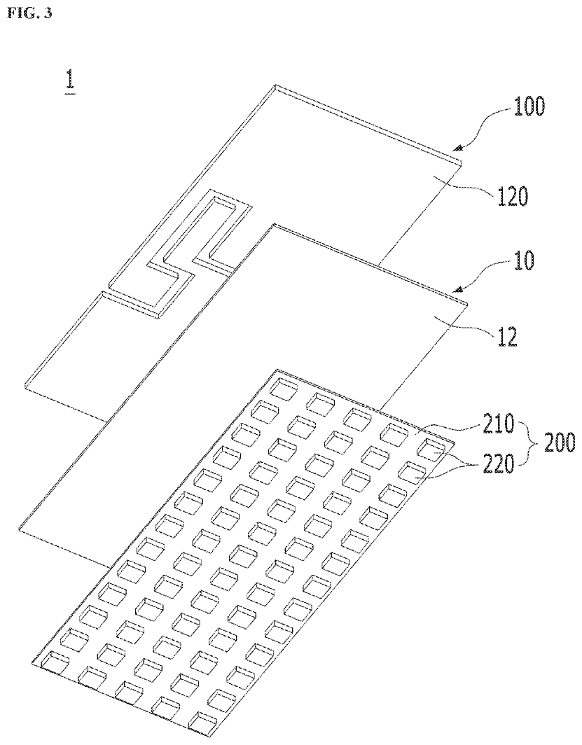

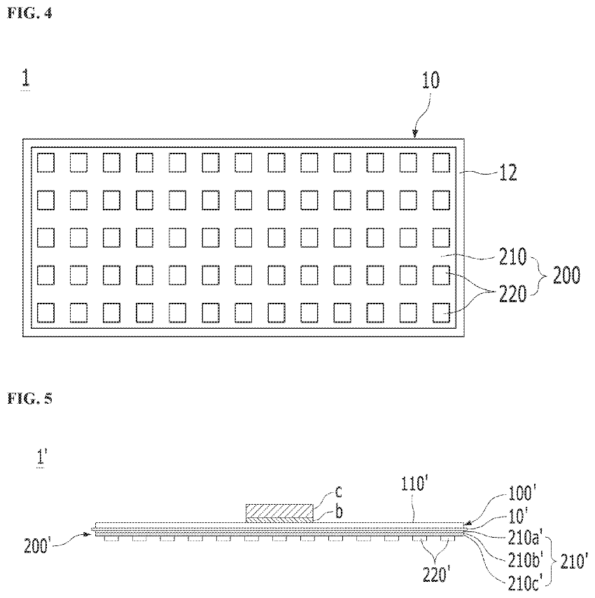

FIG. 1 is a conceptual diagram illustrating a configuration in which a ceramic substrate according to an embodiment of the present disclosure is mounted on a refrigerant circulation unit and a circulation driving unit is connected to the refrigerant circulation unit, FIG. 2 is a perspective view illustrating the ceramic substrate according to the embodiment of the present disclosure, FIG. 3 is an exploded perspective view illustrating a bottom surface side of the ceramic substrate according to the embodiment of the present disclosure, and FIG. 4 is a bottom view illustrating the ceramic substrate according to the embodiment of the present disclosure.

Referring to FIGS. 1 to 4, a ceramic substrate 1 according to an embodiment of the present disclosure may be provided in an integrated form including a ceramic base 10, a first metal sheet 100, and a second metal sheet 200. The ceramic substrate 1 may be an active metal brazing (AMB) substrate in which the first and second metal sheets 100 and 200 are brazed to upper and lower portions of the ceramic base 10.

The ceramic substrate 1 may have a semiconductor chip c mounted on an upper surface 110 of the first metal sheet 100 forming a circuit pattern. The semiconductor chip c may be a semiconductor chip formed of SiC, GaN, Si, a light emitting diode (LED), a vertical cavity surface emitting laser (VCSEL), or the like. The semiconductor chip c may be bonded to the upper surface of the first metal sheet 100 in the form of a flip chip by a bonding layer b containing solder or Ag paste.

The ceramic base 10 may be made of an oxide-based or nitride-based ceramic material. For example, the ceramic base 10 may be any one of alumina (Al₂O₃), AlN, SiN, Si₃N₄, and zirconia toughened alumina (ZTA), but is not limited thereto.

For example, the first metal sheet 100 and the second metal sheet 200 may be made of one of Cu, Al, and a Cu alloy with excellent thermal conductivity.

The first metal sheet 100 may be bonded to the upper portion of the ceramic base 10 and provided in the shape of a circuit pattern. The first metal sheet 100 may be brazed to the upper surface of the ceramic base 10 and formed as an electrode pattern for mounting the semiconductor chip and an electrode pattern for mounting a driving device. For example, the first metal sheet 100 may be formed as an electrode pattern in a region in which the semiconductor chips or peripheral components are mounted. In addition, a thickness of the first metal sheet 100 may be 0.6 T.

The second metal sheet 200 may be bonded to the lower portion of the ceramic base 10. The second metal sheet 200 may include a flat portion 210 and a plurality of heat dissipation fins 220. For example, a thickness of the flat portion 210 may be 0.2 T, and thicknesses of the plurality of heat dissipation fins 220 may be 0.6 T.

Since the flat portion 210 is a portion that is in direct contact with a lower surface 12 of the ceramic base 10, the flat portion 210 may be formed in a flat shape to increase a bonding strength by maximizing a bonding area with the ceramic base 10.

The plurality of heat dissipation fins 220 may be formed to protrude from the lower portion of the flat portion 210 at intervals. In the embodiment, an example in which the plurality of heat dissipation fins 220 have a quadrangular pillar shape is illustrated, but the present disclosure is not limited thereto, and the plurality of heat dissipation fins 220 may be provided in various shapes such as a cylindrical shape, a teardrop shape, or a diamond shape, and the shape of the heat dissipation fin can be implemented through mold machining, etching machining, milling machining, or other machining.

The plurality of heat dissipation fins 220 may be disposed on the refrigerant circulation unit 2. The refrigerant circulation unit 2 may include an inlet 2a through which liquid refrigerant flows, an outlet 2b through which the liquid refrigerant is discharged, and an internal flow path (not illustrated) from the inlet 2a to the outlet 2b. In this case, the liquid refrigerant introduced through the inlet 2a of the refrigerant circulation unit 2 may be discharged through the outlet 2b after passing through the internal flow path. Since a shape and size of the internal flow path, which is a path through which the liquid refrigerant flows between the inlet 2a and the outlet 2b, may be designed variously, detailed description of the internal flow path of the refrigerant circulation unit 2 will be omitted.

The circulation driving unit 3 may be connected to the refrigerant circulation unit 2 and may circulate the liquid refrigerant using a driving force of a pump (not illustrated). Here, the inlet 2a of the refrigerant circulation unit 2 may be connected to the circulation driving unit 3 through a first circulation line L1, and the outlet 2b of the refrigerant circulation unit 2 may be connected to the circulation driving unit 3 through a second circulation line L2. In other words, the circulation driving unit 3 may consecutively circulate the liquid refrigerant along a circulation path including the first circulation line L1, the refrigerant circulation unit 2, and the second circulation line L2. Here, the liquid refrigerant may be deionized water, but is not limited thereto, and may use liquid nitrogen, alcohol, or other solvents if necessary.

The liquid refrigerant supplied from the circulation driving unit 3 may flow into the inlet 2a of the refrigerant circulation unit 2 through the first circulation line L1, discharged through the outlet 2b by moving along the internal flow path formed in the refrigerant circulation unit 2, and then may flow back to the circulation driving unit 3 through the second circulation line L2. Although not illustrated in detail, the circulation driving unit 3 may include a heat exchanger (not illustrated). The heat exchanger of the circulation driving unit 3 may decrease a temperature of the liquid refrigerant of which a temperature has increased while passing through the internal flow path of the refrigerant circulation unit 2, and the circulation driving unit 3 may supply the liquid refrigerant of which the temperature has been decreased by the heat exchanger back to the first circulation line L1 using the driving force of the pump.

As described above, the refrigerant circulation unit 2 may be provided so that the liquid refrigerant supplied from the circulation driving unit 3 circulates consecutively. In this case, the plurality of heat dissipation fins 220 of the ceramic substrate 1 may be disposed in the internal flow path of the refrigerant circulation unit 2 and may be in direct contact with the liquid refrigerant consecutively circulating along the internal flow path. In other words, the ceramic substrate 1 according to the embodiment of the present disclosure has a water-cooled heat dissipation structure in which the plurality of heat dissipation fins 220 may be directly cooled by the consecutively circulating liquid refrigerant.

Since the second metal sheet 200 including the plurality of heat dissipation fins 220 is a state of being in contact with the lower surface 12 of the ceramic base 10 and is made of a metal material with high thermal conductivity, it is possible to easily perform the heat exchange with the ceramic base 10. For example, the second metal sheet 200 may be a metal sheet made of Cu, and since the Cu metal sheet has a thermal conductivity of 393 W/m·° C., it is possible to smoothly perform the heat exchange with the ceramic base 10.

By forcibly cooling the plurality of heat dissipation fins 220 by the consecutively circulating liquid refrigerant even when high-temperature heat is generated from the semiconductor chip c, it is possible to prevent the overheating of the ceramic base 10 and maintain the ceramic base at the constant temperature to prevent the deterioration of the semiconductor chip c. In other words, since the temperature of the liquid refrigerant circulating along the internal flow path of the refrigerant circulation unit 2 is about 25° C. even when the high temperature heat of about 100° C. is generated from the semiconductor chip c, it is possible to quickly cool the heat transferred to the plurality of heat dissipation fins 220.

As described above, the ceramic substrate 1 according to the embodiment of the present disclosure is a configuration in which a heat sink with a pin-fin structure and the ceramic substrate are integrated, and it is possible to simplify the process, save energy and cost, and increase heat dissipation performance while achieving weight reduction and miniaturization. The heat dissipation structure according to the related art is a structure in which a metal layer of a ceramic substrate and a base plate are soldered by using a thermal grease such as an Ag epoxy, and then are coated with a thermal interface materials (TIM) material such as graphite. Since the conventional heat dissipation structure is an indirect cooling type that dissipates heat in a state of stacking several layers of cooling members, the thermal conductivity is as low as about 90 W/m·° C., and thus there is a problem in that not only cooling efficiency is low, but also the manufacturing process is complicated.

Meanwhile, since the ceramic substrate 1 according to the present disclosure has a direct cooling structure that is formed by directly brazing the second metal sheet 200 including the plurality of heat dissipation fins 220 to the lower surface of the ceramic base 10, it is possible to improve mass-productivity and maximize the heat dissipation effect because the thermal conductivity is about 4 times higher than that of the conventional one. In addition, since the ceramic substrate 1 has the water-cooled heat dissipation structure, the ceramic substrate 1 can quickly absorb and dissipate heat by varying the flow rate of the liquid refrigerant, thereby maximizing the heat dissipation effect compared to the conventional air-cooled heat dissipation structure.

In addition, since the liquid refrigerant flows between the plurality of heat dissipation fins 220, there is an advantage in that the flow of the liquid refrigerant can be easily controlled by changing the number and arrangement of plurality of heat dissipation fins 220.

The shapes and number of plurality of heat dissipation fins 220 may be changed variously according to preliminary simulation results during design. In an exemplary embodiment, the plurality of heat dissipation fins 220 may have an aspect ratio of 1:3. When the plurality of heat dissipation fins 220 have the aspect ratio of 1:3, heat may be transferred better and the liquid refrigerant may flow relatively more easily compared to when having an aspect ratio of 1:1.

Meanwhile, although not illustrated, the ceramic base 10, the first metal sheet 100, and the second metal sheet 200 may be bonded by a bonding layer (not illustrated). In this case, the bonding layer may be made of a material containing at least one of Ag and AgCu. Ag and AgCu may function to increase the bonding strength due to the high thermal conductivity and at the same time, facilitate heat transfer to increase the heat-dissipation efficiency. The bonding layer may be formed by any one method of plating, paste application, and foil attachment and may have a thickness of about 0.3 to 3.0 μm.

The bonding layer may be disposed between a lower surface 120 of the first metal sheet 100 and an upper surface 11 of the ceramic base 10 and between a lower surface 12 of the ceramic base 10 and the flat portion 210 of the second metal sheet 200 and may integrally bond the ceramic base 10, the first metal sheet 100, and the second metal sheet 200 at a brazing temperature. The brazing temperature may be in a range of 800 to 950° C. The brazing is to bond base materials by permeating and diffusing the bonding layer between the base materials to be bonded after melting only the bonding layer at temperatures of melting points or less of the base materials using a wetting phenomenon, a capillary phenomenon, and the like and has excellent bonding reliability due to an excellent bonding strength compared to general welding bonding or the like.

Meanwhile, the ceramic base 10, the first metal sheet 100, and the second metal sheet 200 may be bonded by thermochemical bonding. The thermochemical bonding may be bonding using heat fusion, an adhesive, a gluing agent, or the like. Alternatively, the ceramic base 10, the first metal sheet 100, and the second metal sheet 200 may be temporarily bonded by using the thermochemical bonding and then brazed.

As described above, the ceramic base 10, the first metal sheet 100, and the second metal sheet 200 may be airtightly bonded through brazing bonding or thermochemical bonding and bonded to have high bonding strength capable of withstanding water pressure, hydraulic pressure, or the like.

FIG. 5 is a side view illustrating a modified example in which the ceramic substrate according to the embodiment of the present disclosure has a different flat portion of a second metal sheet.

A flat portion 210′ of a ceramic substrate 1′ according to the modified example of FIG. 5 may have a multilayer structure. In this case, at least two adjacent layers of the multi-layer structure may be made of different metal materials.

Specifically, the flat portion 210′ may include an intermediate layer 210b′, an upper metal layer 210a′ formed on an upper surface of the intermediate layer 210b′, and a lower metal layer 210c′ formed on a lower surface of the intermediate layer 210b′. In this case, the upper metal layer 210a′ and the lower metal layer 210c′ are made of the same metal material, and the intermediate layer 210b′ may be made of a different metal material than the upper metal layer 210a′ and the lower metal layer 210c′.

For example, the material of the intermediate layer 210b′ may be any one of CuMo and Mo, and the materials of the upper metal layer 210a′ and the lower metal layer 210c′ may be any one of Cu, Al, and a Cu alloy.

Here, when the upper metal layer 210a′ and the lower metal layer 210c′ are formed of a metal layer made of Cu, and the intermediate layer 210b′ is a CPC material formed of a metal layer made of CuMo, CuMo is to prevent the occurrence of bending due to a low thermal expansion coefficient. and Cu is to secure thermal conductivity for heat dissipation.

CuMo has a relatively lower coefficient of thermal expansion than Cu. Cu has a coefficient of thermal expansion of 17 ppm/° C. and a thermal conductivity of 393 W/m·° C., and CuMo has a coefficient of thermal expansion of 7.0 ppm/° C. and a thermal conductivity of 160 W/m·° C.

As described above, when there is provided a flat portion 210′ with a three-layer structure in which the upper metal layer 210a′ and the lower metal layer 210c′, which are made of the Cu material that has a relatively higher coefficient of thermal expansion but has a higher thermal conductivity, are bonded to upper and lower portions of the intermediate layer 210′ made of the CuMo material with a relatively lower coefficient of thermal expansion, it is possible to prevent the bending phenomenon at high temperatures by decreasing the coefficient of thermal expansion.

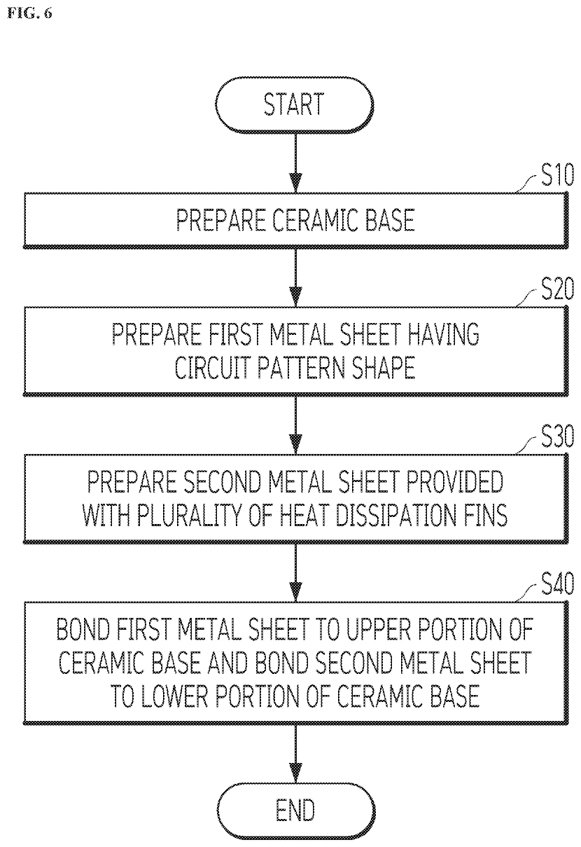

FIG. 6 is a flowchart illustrating a method of manufacturing the ceramic substrate according to the embodiment of the present disclosure.

The method of manufacturing the ceramic substrate according to the embodiment of the present disclosure may include preparing the ceramic base 10 (S10), preparing the first metal sheet 100 having a circuit pattern shape (S20), preparing the second metal sheet 200 provided with the plurality of heat dissipation fins 220 (S30), and bonding the first metal sheet 100 to the upper portion of the ceramic base 10 and bonding the second metal sheet 200 to the lower portion of the ceramic base 10 (S40). Here, the preparing of the ceramic base 10 (S10), the preparing of the first metal sheet 100 (S20), and the preparing of the second metal sheet 200 (S30) may be performed sequentially or performed in a changed order and performed substantially at the same time.

In the preparing of the ceramic base 10 (S10), the ceramic base 10 may be any one of alumina (Al₂O₃), AlN, SiN, Si₃N₄, and zirconia toughened alumina (ZTA), but is not limited thereto.

In the preparing of the first metal sheet 100 having the circuit pattern shape (S20), the first metal sheet 100 may be made of one of Cu, Al, and a Cu alloy and provided in the circuit pattern shape. The thickness of the first metal sheet 100 may be 0.6 T.

In the preparing of the second metal sheet 200 (S30), the second metal sheet 200 may be made of one of Cu, Al, and a Cu alloy and may include the flat portion 210 and the plurality of heat dissipation fins 220. For example, a thickness of the flat portion 210 may be 0.2 T, and thicknesses of the plurality of heat dissipation fins 220 may be 0.6 T. The plurality of heat dissipation fins 220 may be formed to protrude from the lower portion of the flat portion 210 in contact with the lower surface of the ceramic base 10 at intervals. The plurality of heat dissipation fins 220 may be disposed in the internal flow path of the refrigerant circulation unit 2 and may be provided to be in direct contact with the liquid refrigerant consecutively circulating along the internal flow path.

The plurality of heat dissipation fins 220 may be provided in various shapes such as a cylindrical shape, a teardrop shape, or a diamond shape, and the shape of the heat dissipation fin can be implemented through mold machining, etching machining, milling machining, or other machining. In the present embodiment, an example in which the plurality of heat dissipation fins 220 are formed in the preparing of the second metal sheet 200 is described, but the plurality of heat dissipation fins 220 may be formed after the bonding (S40). For example, the plurality of heat dissipation fins 220 may be formed by preparing the second metal sheet 200 having a thick flat shape, bonding the second metal sheet 200 to the lower portion of the ceramic base 10, and then removing a portion of the second metal sheet 200 by etching machining, milling machining, or the like.

The bonding of the first metal sheet 100 to the upper portion of the ceramic base 10 and bonding of the second metal sheet 200 to the lower portion of the ceramic base 10 (S40) may include arranging the bonding layer (S41) and brazing (S42).

In the arranging of the bonding layer (S41), the bonding layer made of a material containing at least one of Ag and AgCu may be disposed by any one method of plating, paste application, and foil attachment. In this case, the bonding layer may be disposed between the lower surface 120 of the first metal sheet 100 and the upper surface 11 of the ceramic base 10 and between the lower surface 12 of the ceramic base 10 and the flat portion 210 of the second metal sheet 200.

After the arranging of the bonding layer (S41), the brazing of the first metal sheet 100, the ceramic base 10, and the second metal sheet 200 (S42) may be performed. In the brazing (S42), the first metal sheet 100, the ceramic base 10, and the second metal sheet 200 may be brazed by melting the bonding layer interposed between the layers at 800 to 950° C. in a stacked state, and at this time, a weight or pressing may be applied to the top in order to increase the bonding strength.

The best embodiments of the present disclosure have been disclosed in the drawings and the specification. Here, although specific terms are used, they are used only for the purpose of describing the present disclosure and are not used to limit the meaning or scope of the present disclosure described in the claims. Therefore, those skilled in the art will understand that various modifications and equivalent embodiments are possible from the present disclosure. Therefore, the true technical scope of the present disclosure should be determined by the technical spirit of the appended claims.

1. A ceramic substrate comprising:
a ceramic base;
a first metal sheet bonded to an upper portion of the ceramic base and provided in a circuit pattern shape; and
a second metal sheet bonded to a lower portion of the ceramic base,
wherein the second metal sheet includes:
a flat portion in contact with a lower surface of the ceramic base; and
a plurality of heat dissipation fins formed to protrude from a lower portion of the flat portion at intervals and in contact with liquid refrigerant.

2. The ceramic substrate of claim 1, wherein the plurality of heat dissipation fins are disposed in a refrigerant circulation unit in which an internal flow path from an inlet to an outlet is formed and are in direct contact with the liquid refrigerant consecutively circulating along the internal flow path.

3. The ceramic substrate of claim 1, wherein the plurality of heat dissipation fins have an aspect ratio of 1:3.

4. The ceramic substrate of claim 1, wherein materials of the first metal sheet and the second metal sheet are any one of Cu, Al, and a Cu alloy.

5. The ceramic substrate of claim 1, further comprising a bonding layer disposed between a lower surface of the first metal sheet and an upper surface of the ceramic base and between the lower surface of the ceramic base and the flat portion of the second metal sheet,
wherein the bonding layer is made of a material including at least one of Ag and AgCu.

6. The ceramic substrate of claim 1, wherein the flat portion has a multi-layer structure and at least adjacent two layers of the multi-layer are made of different metal materials.

7. The ceramic substrate of claim 6, wherein the flat portion includes:
an intermediate layer;
an upper metal layer formed on an upper surface of the intermediate layer; and
a lower metal layer formed on a lower surface of the intermediate layer,
the upper metal layer and the lower metal layer are made of the same metal material, and
the intermediate layer is made of a different metal material from the upper metal layer and the lower metal layer.

8. The ceramic substrate of claim 7, wherein a material of the intermediate layer is any one of CuMo and Mo, and
materials of the upper metal layer and the lower metal layer are any one of Cu, Al, and a Cu alloy.

9. A method of manufacturing a ceramic substrate, comprising:
preparing a ceramic base;
preparing a first metal sheet having a circuit pattern shape;
preparing a second metal sheet provided with a plurality of heat dissipation fins; and
bonding the first metal sheet to an upper portion of the ceramic base and bonding the second metal sheet to a lower portion of the ceramic base,
wherein in the preparing of the second metal sheet,
the plurality of heat dissipation fins are formed to protrude from a lower portion of a flat portion in contact with a lower surface of the ceramic base at intervals and provided to be in contact with liquid refrigerant.

10. The method of claim 9, wherein the bonding includes:
arranging a bonding layer between a lower surface of the first metal sheet and an upper surface of the ceramic base and between the lower surface of the ceramic base and the flat portion of the second metal sheet; and
brazing the first metal sheet, the ceramic base, and the second metal sheet by melting the bonding layer.

11. The method of claim 10, wherein in the arranging of the bonding layer, the bonding layer made of a material including at least one of Ag and AgCu is disposed by any one method of plating, paste application, and foil attachment.
